(19) United States
(12) Patent Application Publication
(10) Pub. No.: US 2009/0275164 A1
(43) Pub. Date: Nov. 5, 2009

(54) BICYCLIC GUANIDINATES AND BRIDGING DIAMIDES AS CVD/ALD PRECURSORS

(75) Inventors: Tianniu Chen, Rocky Hill, CT (US); William Hunks, Waterbury, CT (US); Chongying Xu, New Milford, CT (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 12/434,485

(22) Filed: May 1, 2009

Related U.S. Application Data
(60) Provisional application No. 61/050,129, filed on May 2, 2008.

(51) Int. Cl. H01L 37/00; B05D 7/24; B05D 5/12; C07F 15/00; C07F 3/06

(52) U.S. Cl. 438/54; 427/255.6; 427/126.1; 544/225; 544/226

(57) ABSTRACT

Precursors for use in depositing metal-containing films on substrates such as wafers or other microelectronic device substrates, as well as associated processes of making and using such precursors, and source packages of such precursors. The precursors are useful for depositing Ge₂Sb₂Te₅ chalcogenide thin films in the manufacture of nonvolatile Phase Change Memory (PCM) devices, by deposition techniques such as chemical vapor deposition (CVD) and atomic layer deposition (ALD).

### CROSS REFERENCE TO RELATED APPLICATIONS

The benefit of priority of U.S. Patent Application No. 61/050,129 filed May 2, 2008 is hereby claimed under the provisions of 35 U.S.C. 119. The disclosure of said U.S. Provisional Patent Application No. 61/050,129 is hereby incorporated herein in its respective entirety, for all purposes.

### FIELD OF THE INVENTION

The present invention relates to precursors for use in depositing metal-containing films on substrates such as wafers or other microelectronic device substrates, as well as associated processes of making and using such precursors, and source packages of such precursors.

### DESCRIPTION OF THE RELATED ART

The scaling of microelectronic devices to <90 nm feature sizes has driven the search for chemical vapor deposition (CVD) and atomic layer deposition (ALD) precursors for the low-temperature deposition of thin films in high-aspect ratio structures. Requirements for precursors include: ability to achieve conformal and smooth films, deposition of proper phase and non-segregated character for multi-component alloys, and have high-volatility and thermal stability for vapor transport to heated substrates.

Guanidinate ligands have been used to enhance the thermal stability of potential CVD/ALD precursors because of its bidentate coordination tendency. At the same time, the tunability of the guanidinate ligands could lead to further delocalization of the electron density within NCN units and offer the opportunity for deposition at low temperatures. General routes to make this type of precursor could be summarized as the following: (1) Salt elimination; (2) alkane/amine elimination; (3) transmetallation/metallation; (4) metal-amide insertion. However the choice of the guanidinate ligands is limited by their availability, especially by the availability of the carbodiimides in the salt elimination or metal-amide insertion reactions. Moreover, typical guanidinate ligands contain a pendant dialkylamide group coordinated to the electron-deficient carbon center in the NCN unit {e.g. R₂NC(RN)₂]ₓM}, which can undergo a thermally induced retro-insertion reaction of carbodiimide or undergo a molecular rearrangement producing a metal-amide. Hence these precursors display poor thermal stability during transport in CVD/ALD chambers. Binding the dialkylamide group in a ring structure to prevent this decomposition reaction would provide precursors with better thermal stability for vapor transport, while maintaining the electron delocalization and bonding characteristics that make metal-guanidinates excellent CVD/ALD precursors for conformal low-temperature deposition of metal or metalloid based films.

On the other hand, transition metal diamides or silylamides have also been widely used as CVD/ALD precursors to grow metal, metal oxides, metal nitrides and M-O—Si or M-N—Si ternary films. However, little has been studied on bridging diamide precursors despite their wide potential for ligand variation and straightforward synthesis. One reason could be the flexibility in the bridging diamide backbone that can lead to non-cyclic coordination rather than ligand chelation resulting in dimeric, oligomeric, or polymeric structures. In addition, the saturated bridging group is typically unconjugated which often leads to higher nuclearity complexes that do not meet the volatility requirement for CVD/ALD precursors.

As a result, it would be advantageous to provide additional ligands for producing monomeric CVD/ALD precursors. The present invention provides such ligands, as well as the CVD/ALD precursors, metal-containing films formed from these precursors, and source packages of these precursors.

### SUMMARY OF THE INVENTION

The present invention relates to organometallic precursors useful for depositing metal-containing films on substrates such as wafers or other microelectronic device substrates, as well as associated processes of making and using such precursors, and source packages of such precursors.

In one embodiment, the invention relates to bicyclic guanidinate precursors with the following formula:

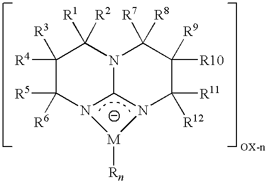

wherein
M is a metal, such as Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Ag, Sr, Bi, and the like; but not Cu
A is an alkali metal,
OX is the oxidation state of the metal,

n is integers from 0 to OX

R₁₋₁₂ are, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl and acetylalkyl, and

R is, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl, amidinates, guanidinates, isourates, β-diketonates, ketoiminates, ketiminates and acetylalkyl, and

In another embodiment, the invention is directed to metal-organic precursors of the formulas:

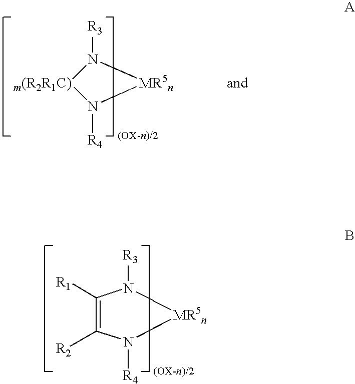

wherein:
M is a metal, such as Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like;
OX is the oxidation state of the metal,

n is integers from 0 to OX and (OX-n)/2 has to be integers at the same time and

R₁₋₄ are, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl and acetylalkyl, and

R₅ is, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl, amidinates, guanidinates, isourates, β-diketonates, ketoiminates, ketiminates and acetylalkyl, and

The organometallic precursors can be included in a composition comprising: the organometallic precursor and a solvent medium in which the compound is dissolved. A further aspect of the invention relates a precursor vapor comprising vapor of an organometallic precursor described above.

The organometallic precursors can be used to deposit a metal-containing film, such as a film comprising one or more of Sb, Bi, Te, Ge, Zr, Ti, Sr, Ba, La Hf and the like, on a substrate. The method for depositing the film comprises volatilizing an organometallic precursor to form a precursor vapor, and contacting the substrate with the precursor vapor under deposition conditions to form the metal-containing film on the substrate. The organometallic precursors have one of the formulae described above.

A further aspect of the invention relates to a packaged precursor, comprising a precursor storage and vapor dispensing vessel having disposed therein an organometallic precursor with the formula described above.

The precursors can for example be used to form a GST film on a substrate, by depositing one or more of germanium, tellurium, or antimony analogues of the bicyclic guanidinates or metal bridging diamides described above on the substrate from a vapor comprising the precursor.

The precursors can also be used to form PCRAM devices, by forming a GST film on a substrate for fabrication of said device. The forming step comprises depositing germanium, tellurium, and/or antimony analogues of the bicyclic guanidinates or metal diamides described above on the substrate from a vapor comprising the precursor.

The bicyclic guanidinate precursors described above can be prepared, for example, by reacting a suitable bicyclic guanidinate of the following formula:

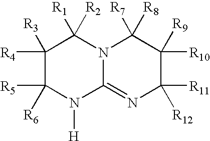

with a metal compound of the following formula: M(Rₙ)X_{OX-n} to yield said organometallic compound, of the formula:

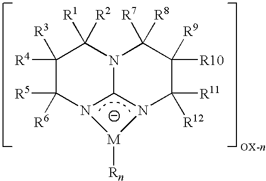

where M is germanium, tellurium, antimony, a transition metal, or other suitable metal, and OX is the oxidation state of the metal.

These precursors can also be prepared by reacting a suitable bicyclic guanidinate of the following formula:

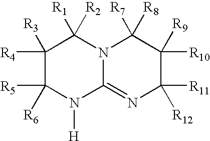

With a strong base (e.g. alkyl lithium, metal hydride) to form an intermediate of the formula:

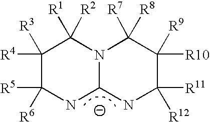

Where R₁₋₁₂ are as described above, and reacting the intermediate with a metal compound of the formula M(R)ₙX_{OX-n}, to yield said organometallic compound.

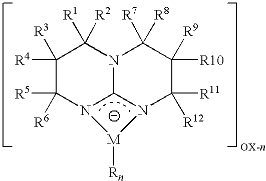

M is a metal, such as Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like;

n is an integer from 0 to OX

The diamide precursors can be prepared, for example, using the following process:

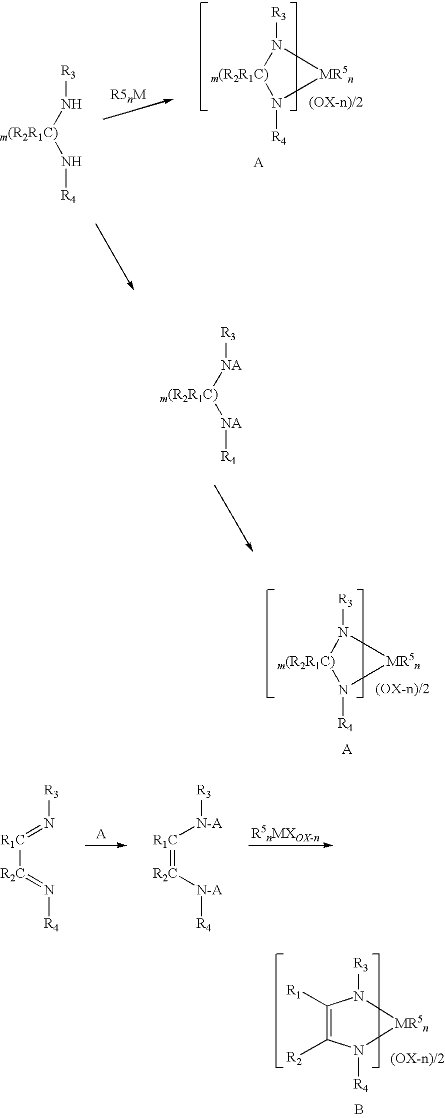

M is a metal, such as Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like;

R₁₋₄ are, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl and acetylalkyl, and

R₅ is, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl, amidinates, guanidinates, isourates, β-diketonates, ketoiminates, ketiminates and acetylalkyl, and

X is a halogen.

In one aspect, the invention further relates to a method of combating pre-reaction of precursors described herein in a vapor deposition process for forming a film on a substrate, wherein the precursors described herein are susceptible to pre-reaction adversely affecting the film. In this aspect, the method involves introducing to the process a pre-reaction-combating agent selected from the group consisting of (i) heteroatom (O, N, S) organo Lewis base compounds, (ii) free radical inhibitors, and (iii) deuterium-containing reagents.

Another aspect of the invention relates to a method of combating pre-reaction of the precursors described in a vapor deposition process in which multiple feed streams are flowed to a deposition locus to form a film on a substrate, wherein at least one of said multiple feed streams includes a precursor susceptible to pre-reaction adversely affecting the film. The method involves introducing to at least one of said multiple feed streams or supplied materials therefor, or to the deposition locus, a pre-reaction-combating agent selected from the group consisting of (i) heteroatom (O, N, S) organo Lewis base compounds, (ii) free radical inhibitors, and (iii) deuterium-containing reagents.

A still further aspect of the invention relates to a composition, comprising a precursor as described herein and a pre-reaction-combating agent for said precursor, said pre-reaction-combating agent being selected from the group consisting of (i) heteroatom (O, N, S) organo Lewis base compounds, (ii) free radical inhibitors, and (iii) deuterium-containing reagents.

In a further aspect, the invention relates to a method of combating pre-reaction of a vapor phase precursor described herein in contact with a substrate for deposition of a film component thereon. The method involves contacting said substrate, prior to said contact of the vapor phase precursor therewith, with a pre-reaction-combating agent selected from the group consisting of (i) heteroatom (O, N, S) organo Lewis base compounds, (ii) free radical inhibitors, and (iii) deuterium-containing reagents.

In a further aspect, the invention relates to a process wherein the pre-reaction combating reagent is introduced to passivate the surface of a growing film or slow the deposition rate, followed by reactivation using an alternative precursor or co-reactant (for example H₂, NH₃, plasma, H₂O, hydrogen sulfide, hydrogen selenide, diorganotellurides, diorganosulfides, diorganoselenides, etc.). Such passivation/retardation followed by reactivation thus may be carried out in an alternating repetitive sequence, for as many repetitive cycles as desired, in ALD or ALD-like processes. Pre-reaction-combating agents can be selected from the group consisting of (i) heteroatom (O, N, S) organo Lewis base compounds, (ii) free radical inhibitors, and (iii) deuterium-containing reagents.

Another aspect of the invention relates to a vapor phase deposition process for forming a film on a substrate involving cyclic contacting of the substrate with at least one film precursor described herein that is undesirably pre-reactive in the vapor phase. The process involves introducing to said film during growth thereof a pre-reaction-combating reagent that is effective to passivate a surface of said film or to slow rate of deposition of said film precursor, and after introducing said pre-reaction-combating reagent, reactivating said film with a different film precursor.

Other aspects, features and embodiments of the invention will be more fully apparent from the ensuing disclosure and appended claims.

### BRIEF DESCRIPTION OF THE DRAWINGS

FIG. 1 is a schematic representation of a material storage and dispensing package containing a precursor of the present invention, in one embodiment thereof.

FIG. 2 is a schematic representation of a vapor deposition system according to one embodiment of the present invention, wherein suppression of pre-reaction of the precursors is achieved by addition of pre-reaction-combating reagent to one or more feed streams in the vapor deposition system.

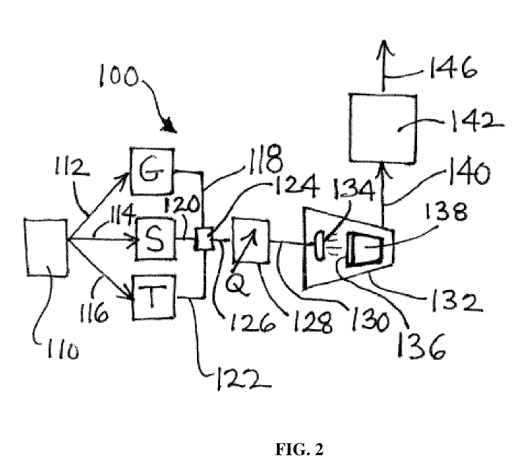

### DETAILED DESCRIPTION

The present invention relates to organometallic precursors, such as germanium, tellurium and/or antimony precursors, useful in film-forming applications, e.g., in chemical vapor deposition and atomic layer deposition applications, to form corresponding germanium, antimony, and/or tellurium-containing films on substrates, as well as associated processes of making and using such precursors, and packaged forms of such precursors. Such precursors are useful for the deposition of Ge₂Sb₂Te₅ chalcogendie thin films for nonvolatile phase-change memory (PCM) devices.

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved. As used herein, the term “thin film” means a layer of a material having a thickness below 1 micrometer. In addition, thin films refers to the deposition of films into narrow trench and via structures <90 nm that involve full-filling of the geometry.

As used herein, the singular forms “a”, “and”, and “the” include plural referents unless the context clearly dictates otherwise.

As used herein, the identification of a carbon number range, e.g., in C₁-C₁₂ alkyl, is intended to include each of the component carbon number moieties within such range, so that each intervening carbon number and any other stated or intervening carbon number value in that stated range, is encompassed, it being further understood that sub-ranges of carbon number within specified carbon number ranges may independently be included in smaller carbon number ranges, within the scope of the invention, and that ranges of carbon numbers specifically excluding a carbon number or numbers are included in the invention, and sub-ranges excluding either or both of carbon number limits of specified ranges are also included in the invention. Accordingly, C₁-C₁₂ alkyl is intended to include methyl, ethyl, propyl, butyl, pentyl, hexyl, heptyl, octyl, nonyl, decyl, undecyl and dodecyl, including straight chain as well as branched groups of such types. It therefore is to be appreciated that identification of a carbon number range, e.g., C₁-C₁₂, as broadly applicable to a substituent moiety, enables, in specific embodiments of the invention, the carbon number range to be further restricted, as a sub-group of moieties having a carbon number range within the broader specification of the substituent moiety. By way of example, the carbon number range C₁-C₁₂ alkyl, may be more restrictively specified, in particular embodiments of the invention, to encompass sub-ranges such as C₁-C₄ alkyl, C₂-C₈ alkyl, C₂-C₄ alkyl, C₃-C₅ alkyl, or any other sub-range within the broad carbon number range.

The precursors of the invention may be further specified in specific embodiments by provisos or limitations excluding specific substituents, groups, moieties or structures, in relation to various specifications and exemplifications thereof set forth herein. Thus, the invention contemplates restrictively defined compositions, e.g., a composition wherein Rⁱ is C₁-C₁₂ alkyl, with the proviso that Rⁱ≠C₄ alkyl when R^{j} is silyl.

The invention relates in one aspect to germanium, tellurium, or antimony precursors useful for low temperature (T<400° C.) deposition of Te-containing, Ge-containing, or Sb-containing films, e.g., for forming germanium-antimony-tellurium (GST) films such as Ge₂Sb₂Te₅ on substrates such as wafers in the production of phase change random access memory devices. In another aspect, the precursors include other metals, such as transition metals.

Transition metals include those in Groups IB to VIIIB of the periodic table, and specifically include iron, cobalt, nickel, ruthenium, rhodium, palladium, osmium, iridium, platinum, gold, Ti, Zr, Ba, Sr, Hf, Mn and the lanthanide series. Organometallic precursors including these metals can be used in ALD/CVD processes, for example, to produce electrodes, and capacitors including these electrodes.

The precursors of the invention are suitable for forming such films by techniques such as atomic layer deposition (ALD) and chemical vapor deposition (CVD). Preferred precursors of such type have high volatility and desirable transport properties for ALD and CVD applications.

### I. Bicyclic Guanidinate Precursors

In one embodiment, the invention is directed to organometallic precursors having the formula

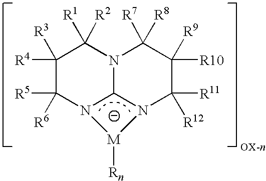

where M is, in one embodiment, germanium, tellurium, or antimony, or, in another embodiment, is Bi, Te, or another metal, and R¹⁻¹² are organo substituents, are employed to form Te-containing, Ge-containing, or Sb-containing highly conformal films of superior character by a vapor deposition process such as ALD or CVD.

In a preferred aspect, each of R₁₋₁₂ is, independently, selected from H, halogen (fluorine, bromine, iodine and chlorine), C₁-C₆ alkyl, C₁-C₆ alkoxy, C₃-C₈ cycloalkyl, C₆-C₁₀ aryl, silyl, substituted silyl (silyl having C₁-C₆ alkyl substituents and/or C₆-C₁₀ aryl substituents), amide, aminoalkyl, alkylamine, alkoxyalkyl, aryloxyalkyl, imidoalkyl and acetylalkyl. The alkyl moiety in such aminoalkyl, alkylamine, alkoxyalkyl, aryloxyalkyl, imidoalkyl and acetylalkyl substituents can be C₁-C₆ alkyl or alkyl moieties of other carbon numbers, as may be useful in a given application of such organyl compounds. The invention in a further aspect relates to a novel synthetic route for the preparation of bicyclic guanidinate Ge, Sb, Te, Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like; or other organometallic compounds.

In a specific aspect, the invention provides germanium, antimony, or tellurium bicyclic guanidinates that are useful for low temperature deposition of germanium, antimony, or tellurium on substrates.

The present invention contemplates a method for the preparation of Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like; or other precursors, using a suitably functionalized bicyclic guanidinate as a starting material, and a metal ion suitably functionalized with one or more ligands and one or more halogens, as shown below in Scheme I.

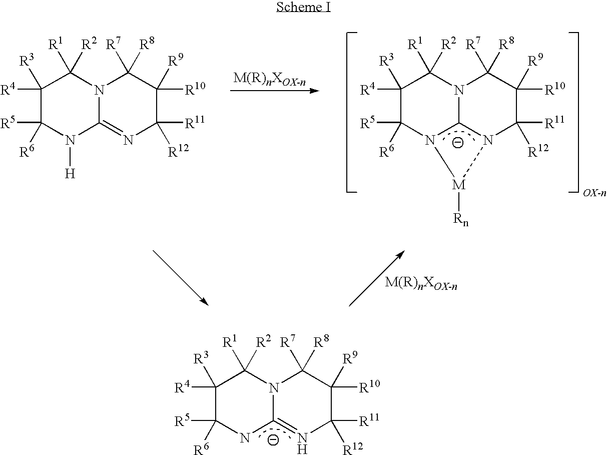

wherein:

X is halogen, preferably Cl, Br or I,

M is a metal, such as Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Ag, Sr, Bi, and the like;

R₁₋₁₂ are, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl and acetylalkyl, and

R is, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl, amidinates, guanidinates, isourates, β-diketonates, ketoiminates, ketiminates and acetylalkyl, and

OX is the oxidation state of the metal, and

n is integers from 0 to OX integers
n is integers from 0 to OX and (OX−n)/2 has to be integers at the same time

The bicyclic guanidinates used to prepare the organometallic precursors are either commercially-available, such as 13,4,6,7,8-hexahydro-2H-pyrimido [1,2-a]pyrimidine (HPP) or can be prepared using the same or similar synthetic methodology used to prepare hpp.

### II. Diamide Precursors

In another embodiment, the invention is directed to organic precursors of the formulas:

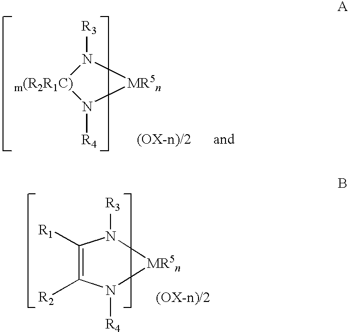

wherein:

M is a metal, such as Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like;

OX is the oxidation state of the metal,

n is integers from 0 to OX and (OX−n)/2 has to be integers at the same time and

R₁₋₄ are, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl and acetylalkyl, and R₅ is, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl, amidinates, guanidinates, isourates, β-diketonates, ketoiminates, ketiminates and acetylalkyl, and

These precursors can be prepared, for example, using the processes shown in Schemes II and III:

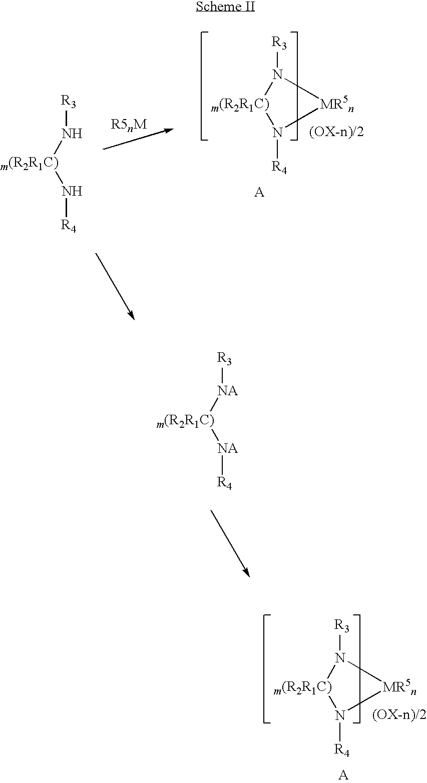

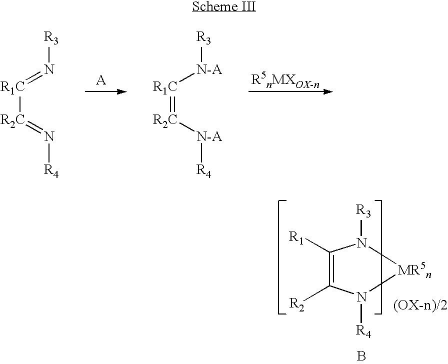

While not wishing to be bound by a particular theory, it is believed that there has been little use of metal diamides as CVD/ALD precursors to grow metal, metal oxides, metal nitrides and M-O—Si or M-N—Si ternary films, at least in part due to the bridging diamide participating in bridging coordination rather than ligand chelation, which leads to higher nuclearity metal complexes or polymeric structures not meeting the volatility requirement for CVD/ALD precursors.

It can be beneficial to use relatively bulky groups such as isopropyl, propyl, butyl, isobutyl, t-butyl, or SiMe₃ on at least one of the nitrogen atoms in these type of ligands and short-chain or rigid conjugated (N—C═C—N) bridging units to enhance the ligand robustness and chelation tendency. This can allow the formation of unusually low coordination numbers and oxidation states for many metals. These transition metal complexes tend to be monomers or low-order oligomers, which are desirable for use as volatile CVD/ALD precursors. At the same time, they tend to have better thermal stability due to the chelate moiety in the precursors.

### III. Use of the Compounds as CVD/ALD Precursors

The compounds described herein have high volatility and low decomposition temperatures. They are well suited for ALD and CVD applications, where they can be usefully employed as CVD/ALD precursors for the deposition of metal-containing films, such as Ge, Sb, or Te-containing films, e.g., by liquid delivery techniques in which such compounds are provided in compositions including suitable solvent media.

Useful solvents for such purposes in specific applications may include, without limitation, alkanes (e.g., hexane, heptane, octane, and pentane), aromatics (e.g., benzene or toluene), and amines (e.g., triethylamine, tert-butylamine). The solvent medium in which the Te precursor or precursors are dissolved or suspended may be a single-component solvent or a multi-component solvent composition.

The precursors when in a liquid state can also be delivered neat using ALD/CVD liquid delivery techniques, in which the liquid is volatilized to form a corresponding precursor vapor, which then is contacted with the substrate on which the tellurium-containing film is to be formed, under appropriate vapor deposition conditions.

When the precursors are in a solid state, they may be volatilized for delivery using any suitable solid delivery system, such as the solid delivery and vaporizer unit commercially available under the trademark ProE-Vap from ATMI, Inc. (Danbury, Conn., USA). The precursor or precursors (since the invention contemplates use of multiple Ge, Sb, or Te precursors of differing type) are volatilized to form the corresponding precursor vapor which then is contacted with a wafer or other substrate to deposit a tellurium-containing layer thereon.

The precursor vapor formed from the Ta, V, Ti, Nb, Pb, Ni, W, Ca, Ba, In, Y, Lanthanides, Zr, Hf, Ir, Ru, Pt, Cr, Mo, Ge, Al, Si, Ga, Sc, V, Cr, Fe, Sb, Mn, Co, Zn, Cd, Te, Hg, Au, Cu, Ag, Sr, Bi, and the like; or other precursor may be mixed with carrier or co-reactant gases in various embodiments, to obtain desired deposition thicknesses, growth rates, etc., as will be apparent to those skilled in the art.

The invention therefore provides germanium, antimony, and/or tellurium compounds of a useful character for ALD or CVD deposition of germanium, antimony, or tellurium-containing films, e.g., for fabricating GST devices comprising Ge₂Sb₂Te₅ films.

Another aspect of the invention relates to germanium, antimony, or tellurium compounds for use in low temperature deposition applications such as fabrication of the aforementioned GST-based phase change memory devices.

These precursors accommodate low temperature deposition applications, having good volatilization and transport properties. They can be delivered in a neat form in the case of precursor compounds in liquid form, or in compositions including suitable solvent media. Useful solvents for such purpose in specific applications may include, without limitation, alkanes (e.g., hexane, heptane, octane, and pentane), aromatics (e.g., benzene or toluene), and amines (e.g., triethylamine, tert-butylamine) or mixtures thereof, as above described.

The precursors when in a solid state can be volatilized for delivery using any suitable solid delivery system, such as the solid delivery and vaporizer unit commercially available under the trademark ProE-Vap from ATMI, Inc. (Danbury, Conn., USA). The precursor or precursors (since the invention contemplates use of multiple Te precursors of differing type) are volatilized to form the corresponding precursor vapor which then is contacted with a wafer or other substrate to deposit a tellurium-containing layer thereon, e.g., for forming a GST layer.

The invention in yet another aspect relates to germanium, antimony, and/or tellurium compounds with nitrogen donor ligands useful for deposition applications to deposit germanium, antimony, and/or tellurium, or germanium, antimony, and/or tellurium-containing films on substrates, for applications such as GST phase change random access memory (PRAM) devices.

When the metal is a transition metal, such as platinum or iridium, the film can form an electrode, for example, as part of a capacitor. The application of transition metal precursors using CVD techniques to form electrode layers is known in the art, and is not discussed further here.

IV. Use of the Precursors with Co-Reactants

The compounds described herein, when used in film formation processes, may be used with appropriate co-reactants, e.g., in a continuous deposition mode (CVD) or pulsed/atomic layer deposition mode (ALD), to deposit films of superior character. For oxides, preferred co-reactants include O₂ and N₂O for CVD, and more aggressive oxidizers for pulsed deposition, e.g., H₂O, ozone, and O₂ plasma. For metal-like films, reducing atmospheres are advantageously used.

The precursors of the invention can be utilized as low temperature deposition precursors with reducing co-reactants such as hydrogen, H₂/plasma, amines, imines, hydrazines, silanes, germanes such as GeH₄, ammonia, alkanes, alkenes and alkynes. For CVD modes of film formation, reducing agents such as H₂, and NH₃ are preferred, and plasmas of these co-reactants may be used in digital or ALD mode, wherein the co-reactants are separated from the precursor in a pulse train, utilizing general CVD and ALD techniques within the skill of the art, based on the disclosure herein. More aggressive reducing agents can also be used in a digital or ALD mode since co-reactants can be separated, preventing gas phase reactions. For ALD and conformal coverage in high aspect ratio structures, the precursor preferably exhibits self-limiting behavior in one type of atmosphere (e.g., inert or weakly reducing/oxidizing gas environments) and exhibits rapid decomposition to form a desired film in another type of atmosphere (e.g., plasma, strongly reducing/oxidizing environments).

Liquid delivery formulations can be employed in which precursors that are liquids may be used in neat liquid form, or liquid or solid precursors may be employed in suitable solvents, including for example alkane solvents (e.g., hexane, heptane, octane, and pentane), aryl solvents (e.g., benzene or toluene), amines (e.g., triethylamine, tert-butylamine), imines and hydrazines or mixtures thereof. The utility of specific solvent compositions for particular precursors may be readily empirically determined, to select an appropriate single component or multiple component solvent medium for the liquid delivery vaporization and transport of the specific tellurium precursor that is employed. In the case of solid precursors of the invention, a solid delivery system may be utilized, for example, using the ProE-Vap solid delivery and vaporizer unit (commercially available from ATMI, Inc., Danbury, Conn., USA).

V. Films Formed from the Precursors

In general, the thicknesses of metal-containing layers formed using the precursors of the invention can be of any suitable value. In a specific embodiment of the invention, the thickness of the metal-containing layer can be in a range of from 5 nm to 500 nm or more and includes filling of high-aspect ratio geometries with cross-sections from 2-250 nm.

The various precursor compounds of the invention can be utilized to form GST films in combination with any suitable germanium and antimony precursors, e.g., by CVD and ALD techniques, for applications such as PCRAM device manufacture. The process conditions useful for carrying out deposition of metal-containing films can be readily determined within the skill of the art by the simple expedient of selectively varying the delivery and deposition process conditions and characterizing the resulting films, to determine the process conditions envelope most appropriate for a given deposition application.

In one specific embodiment of the invention, (Zr(N(Prⁱ)CH₂CH₂CH₂N(Prⁱ))₂ is used as a precursor for forming Zr-containing films on substrates, such as ZrO2 films, by atomic layer deposition (ALD) and chemical vapor deposition (CVD) techniques.

In another embodiment, amorphous GeTe and SbTe are deposited from Ge, Te, and/or Sb-containing precursors described herein, at temperature in a range of from 300° C.-350° C., e.g., 320° C., using bubbler delivery of the precursor in an inert carrier gas stream, e.g., N₂ at a flow rate of 20-50 sccm, e.g., 30 sccm. One or more of the respective germanium tellurium, and antimony precursors used for such deposition can be of any suitable types, e.g., Ge(NMe₂)₄, Ge(iBu)₄, Sb(NMe₂)₃, Sb(iPr)₃, iPr₂Te, tBu₂Te, [nBuC(iPrN)₂]₂Ge, [MeC(iPrN)₂]₂Ge, etc., and such precursors can be delivered for deposition at any suitable volumetric flow rate, e.g., for the aforementioned flow rate of 30 sccm for the precursors described herein, a flow rate of such Ge or Sb precursor can be on the order of 5 micromoles/minute. The resulting amorphous GeTe and SbTe films will have a tellurium content ranging from 20-70%.

VI. Formation of Chalcogenide Films with Pre-Reaction-Combating Agents

The invention in another aspect involves use of control agents to combat vapor phase pre-reaction of the precursors described herein, that otherwise causes uneven nucleation on the substrate, longer incubation times for deposition reactions, and lower quality product films. Such pre-reaction may for example be particularly problematic in applications involving chalcogenide films, related source materials (O, S, Se, Te, Ge, Sb, Bi, etc.), and/or manufacture of phase change memory and thermoelectric devices.

Pre-reaction may occur when the precursor reagents described herein are introduced to the deposition chamber, as in chemical vapor deposition, and may also occur in atomic layer deposition (ALD) processes, depending on the specific arrangement of ALD cycle steps and the specific reagents involved.

The invention therefore contemplates the use of control agents with the precursors described herein, whereby detrimental gas phase pre-reactions are suppressed, mitigated or eliminated, so that deposition reactions are induced/enhanced on the substrate surface, and films of superior character are efficiently formed.

The control agents that can be utilized with precursors of the invention for such purpose include agents selected from the group consisting of (i) heteroatom (O, N, S) organo Lewis base compounds, (ii) free radical inhibitors, and (iii) deuterium-containing reagents.

These agents can be utilized to lessen deleterious gas phase pre-reaction I′ll precursors by various approaches, including:

(1) addition to the precursor composition of a pre-reaction suppressant comprising one or more heteroatom (O, N, S) organo Lewis base compounds such as 1,4-dioxane, thioxane, ethers, polyethers, triethylamine (TEA), triazine, diamines, N,N,N′,N′-tetramethylethylenediamine, N,N,N′-trimethylethylenediamine, amines, imines, and pyridine;

(2) addition to the precursor composition of a free radical inhibitor, such as butylated hydroxy toluene (BHT), hydroquinone, butylated hydro anisole (BHA), diphenylamine, ethyl vanillin, etc.;

(3) use of modified chalcogenide precursors, in which hydrogen substituents have been replaced with deuterium (D) substituents, to provide deuterated analogs for vapor phase deposition; and

(4) addition to the precursor composition of a deuterium source, to deuterate the precursor in situ.

The pre-reaction-combating agents described above (suppressants, free radical inhibitors, deuterium sources and/or deuterated precursors) can be introduced to any of the feed streams to the vapor deposition process in which the film is to be formed. For example, such pre-reaction-combating agents can be introduced to one or more of precursor feed stream(s), inert carrier gas stream(s) to which chalcogenide precursor(s) or other reagents are subsequently added for flow to the deposition chamber, co-reactant feed stream(s) flowed to the deposition chamber, and/or any other stream(s) that is/are flowed to the deposition chamber and in which the pre-reaction-combating agent(s) is/are useful for reduction or elimination of premature reaction of the precursors that would otherwise occur in the absence of such agent(s).

The aforementioned suppressants, free radical inhibitors and/or deuterium source reagents in specific embodiments are co-injected with the precursor(s), e.g., metal source reagent(s), to effect at least partial reduction of pre-reaction involving the precursor(s) and reagent(s).

The pre-reaction-combatting agent can alternatively be added directed to the deposition locus, e.g., the deposition chamber to which the precursor vapor is introduced for contacting with the substrate to deposit the film thereon, to suppress deleterious vapor phase pre-reaction involving the precursor(s) and/or other reagents.

As another approach, in the broad practice of the present invention, the suppressant, free radical inhibitor and/or deuterium source can be added to a solution containing the precursor and/or another metal source reagent, and the resulting solution can be utilized for liquid delivery processing, in which the solution is flowed to a vaporizer to form a source vapor for contacting with the substrate to deposit the deposition species thereon.

Alternatively, if the precursor and/or another metal source reagent are not in an existing solution, the suppressant, free radical inhibitor and/or deuterium source can be added to form a mixture or a solution with the precursor and/or another metal source reagent, depending on the respective phases of the materials involved, and their compatibility/solubility.

As a still further approach, the suppressant, free radical inhibitor and/or deuterium source can be utilized for surface treatment of the substrate prior to contacting of the substrate with the precursor and/or other metal source reagent.

The invention therefore contemplates various vapor deposition compositions and processes for forming films on substrates, in which pre-reaction of the precursors is at least partially attenuated by one or more pre-reaction-combating agents selected from among heteroatom (O, N, S) organo Lewis base compounds, sometimes herein referred to as suppressor agents, free radical inhibitors, and/or deuterium source reagents. Use of previously synthesized deuterated precursors or organometal compounds is also contemplated, as an alternative to in situ deuteration with a deuterium source. By suppressing precursor prereaction with these approaches, product films of superior character can be efficiently formed.

The control agent can be used for combating pre-reaction of chalcogenide precursor in a process in which multiple feed streams are flowed to a deposition locus to form a film on a substrate, wherein at least one of the multiple feed streams includes a precursor susceptible to pre-reaction adversely affecting the film, in which the method involves introducing the control agent to at least one of such multiple feed streams or supplied materials therefor, or to the deposition locus.

The pre-reaction combating reagent alternatively can be introduced to passivate the surface of a growing chalcogenide film or slow the deposition rate, followed by reactivation using an alternative precursor or co-reactant (for example H₂, NH₃, plasma, H₂O, hydrogen sulfide, hydrogen selenide, diorganotellurides, diorganosulfides, diorganoselenides, etc.), thereby carrying out passivation/retardation followed by reactivation steps, e.g., as an alternating repetitive sequence. Such sequence of passivation/retardation followed by reactivation can be carried out for as many repetitive cycles as desired, in ALD or ALD-like processes. The steps may be carried out for the entire deposition operation, or during some initial, intermediate or final portion thereof.

The invention therefore contemplates precursor compositions including the precursor and the pre-reaction-combating reagent. Within the categories of pre-reaction-combating reagents previously described, viz., (i) heteroatom (O, N, S) organo Lewis base compounds, (ii) free radical inhibitors, and (iii) deuterium-containing reagents, suitable pre-reaction-combating reagents for specific applications may be readily determined within the skill of the art, based on the disclosure herein.

Heteroatom (O, N, S) organo Lewis base compounds may be of varied type, e.g., containing an oxo (—O—) moiety, a nitrogen ring atom or pendant amino or amide substituent, a sulfur ring atom or pendant sulfide, sulfonate or thio group, as effective to at least partially lessen pre-reaction of the precursor and other organo metal reagents in the process system. Illustrative examples of heteroatom (O, N, S) organo Lewis base compounds having utility in specific applications of the invention include, without limitation, 1,4-dioxane, thioxane, ethers, polyethers, triethylamine, triazine, diamines, N,N,N′,N′-tetramethylethylenediamine, N,N,N′-trimethylethylenediamine, amines, imines, pyridine, and the like.

The heteroatom organo Lewis base compound in various specific embodiments of the invention may include a guanidinate compound, e.g., (Me₂N)₂C═NH.

One preferred class of heteroatom organo Lewis base compounds for such purpose includes R₃N, R₂NH, RNH₂, R₂N(CH₂)ₙNR₂, R₂NH(CH₂)ₙNR₂, R₂N(CR₂)ₙNR₂, and cyclic amines —N(CH₂)ₓ—, imidazole, thiophene, pyrrole, thiazole, urea, oxazine, pyran, furan, indole, triazole, triazine, thiazoline, oxazole, dithiane, trithiane, crown ethers, 1,4,7-triazacyclononane, 1,5,9-triazacyclododecane, cyclen, succinamide, and substituted derivatives of the foregoing, wherein R can be hydrogen or any suitable organo moieties, e.g., hydrogen, C₁-C₈ alkyl, C₁-C₈ alkoxy, C₁-C₈ alkene, C₁-C₈ alkyne, and C₁-C₈ carboxyl, and wherein x is an integer having a value of from 1 to 6.

The heteroatom organo Lewis base compounds may be utilized in the precursor composition at any suitable concentration, as may be empirically determined by successive deposition runs in which the heteroatom organo Lewis base compound concentration is varied, and character of the resulting film is assessed, to determine an appropriate concentration. In various embodiments, the heteroatom organo Lewis base compound may be utilized in the concentration of 1-300% of the amount of precursor. Specific sub-ranges of concentration values within a range of 0.01-3 equivalents of the heteroatom organo Lewis base compound may be established for specific classes of precursors, without undue experimentation, based on the disclosure herein.

The pre-reaction-combating reagent may additionally or alternatively comprise free radical inhibitors that are effective to lessen the extent of pre-reaction between the precursor and another organo metal reagent. Such free radical inhibitors may be of any suitable type, and may for example include hindered phenols. Illustrative free radical inhibitors include, without limitation, free radical scavengers selected from the group consisting of: 2,6-ditert-butyl-4-methyl phenol, 2,2,6,6-tetramethyl-1-piperidinyloxy, 2,6-dimethylphenol, 2-tert-butyl-4-hydroxyanisole, 3-tert-butyl-4-hydroxyanisole, propyl ester 3,4,5-trihydroxy-benzoic acid, 2-(1,1-dimethylethyl)-1,4 benzenediol, diphenylpicrylhydrazyl, 4-tert-butylcatechol, N-methylaniline, 2,6-dimethylaniline, p-methoxydiphenylamine, diphenylamine, N,N′-diphenyl-p-phenylenediamine, p-hydroxydiphenylamine, phenol, octadecyl-3-(3,5-di-tert-butyl-4-hydroxyphenyl) propionate, tetrakis (methylene (3,5-di-tert-butyl-4-hydroxy-hydrocinnamate) methane, phenothiazines, alkylamidonoisoureas, thiodiethylene bis(3,5,-di-tert-butyl-4-hydroxy-hydrocinnamate, 1,2,-bis(3,5-di-tert-butyl-4-hydroxyhydrocinnamoyl) hydrazine, tris (2-methyl-4-hydroxy-5-tert-butylphenyl) butane, cyclic neopentanetetrayl bis(octadecyl phosphite), 4,4′-thiobis (6-tert-butyl-m-cresol, 2,2′-methylenebis (6-tert-butyl-p-cresol), oxalyl bis(benzylidenehydrazide) and mixtures thereof. Preferred free radical inhibitors include BHT, BHA, diphenylamine, ethyl vanillin, and the like.

Useful concentrations of the free radical inhibitor may be in a range of from 0.001 to about 0.10% by weight of the weight of the precursor, in various specific embodiments. More generally, any suitable amount of free radical inhibitor may be employed that is effective to combat the pre-reaction of the precursor in the delivery and deposition operations involved in the film formation process.

The deuterium source compounds afford another approach to suppressing pre-reaction of the chalcogenide precursor. Such deuterium source compounds may be of any suitable type, and may for example include deuterated pyridine, deuterated pyrimidine, deuterated indole, deuterated imidazole, deuterated amine and amide compounds, deuterated alkyl reagents, etc., as well as deuterated analogs of the precursors that would otherwise be used as containing hydrogen or protonic substituents.

Deuterides that may be useful in the general practice of invention as pre-reaction-combating reagents include, without limitation, germanium and antimony compounds of the formulae RₓGeD₄₋ₓ, and RₓSbD₃₋ₓ wherein R can be hydrogen or any suitable organo moieties, e.g., hydrogen, C₁-C₈ alkyl, C₁-C₈ alkoxy, C₁-C₈ alkene, C₁-C₈ alkyne, and C₁-C₈ carboxyl, and wherein x is an integer having a value of from 1 to 6.

The deuterium source reagent may be utilized at any suitable concentration that is effective to combat pre-reaction of the precursor. Illustrative deuterium source reagent concentrations in specific embodiments of the invention can be in a range of 0.01 to about 5% by weight, based on the weight of precursor.

Thus, a deuterium source compound may be added to one or more of the feed streams to the vapor deposition process, and/or one of the precursors or other feed stream components may be deuterated in the first instance.

The concentrations of the pre-reaction-combating agents utilized in the practice of the present invention to at least partially eliminate pre-reaction of the precursors can be widely varied in the general practice of the present invention, depending on the temperatures, pressures, flow rates and specific compositions involved. The above-described ranges of concentration of the pre-reaction-combating reagents of the invention therefore are to be appreciated as being of an illustrative character only, with applicable concentrations being readily determinable within the skill of the art, based on the disclosure herein.

The specific mode of introduction or addition of the pre-reaction-combating agent to one or more of the feed streams to the deposition process may correspondingly be varied, and may for example employ mass flow controllers, flow control valves, metering injectors, or other flow control or modulating components in the flow circuitry joining the source of the pre-reaction-combating agent with the streams being flowed to the deposition process during normal film-forming operation. The process system may additionally include analyzers, monitors, controllers, instrumentation, etc., as may be necessary or appropriate to a given implementation of the invention.

In lieu of introduction or addition of the pre-reaction-combating agent to one or more of the flow streams to the vapor deposition process, the pre-reaction-combating agent may be mixed with precursor in the first instance, as a starting reagent material for the process. For example, the pre-reaction-combating agent may be mixed in liquid solution with the precursor, for liquid delivery of the resulting precursor solution to a vaporizer employed to generate precursor vapor for contact with the substrate to deposit the film thereon.

As mentioned, the pre-reaction-combating agent may be added to the deposition locus to provide active gas-phase suppression of pre-reaction of the precursor vapor(s) that would otherwise be susceptible to such deleterious interaction.

As a still further alternative, the pre-reaction-combating agent may be used as a preliminary surface treatment following which the precursor and co-reactants (e.g., H₂, NH₃, plasma, H₂O, hydrogen sulfide, hydrogen selenide, diorganotellurides, diorganosulfides, diorganoselenides, etc.) are delivered to the substrate surface to effect deposition on such surface. For such purpose, the pre-reaction-combating agent may be introduced into one of more of the flow lines to the deposition process and flow to the substrate in the deposition process chamber, prior to initiation of flow of any precursors. After the requisite period of contacting of the substrate with such pre-reaction-combating agent has been completed, the flow of the pre-reaction-combating agent can be terminated, and normal feeding of flow streams to the deposition chamber can be initiated.

It will be apparent from the foregoing description that the pre-reaction-combating agent may be introduced in any of a wide variety of ways to effect diminution of the pre-reaction of the precursor in the deposition system.

In one embodiment of the invention, a vapor phase deposition system is contemplated, comprising:

a vapor deposition chamber adapted to hold at least one substrate for deposition of a film thereon;

chemical reagent supply vessels containing reagents for forming the film;

first flow circuitry arranged to deliver said reagents from said chemical reagent supply vessels to the vapor deposition chamber;

a pre-reaction-combating agent supply vessel containing a pre-reaction-combating agent;

second flow circuitry arranged to deliver the pre-reaction-combating agent from the pre-reaction-combating agent supply vessel to the first flow circuitry, to said chemical reagent supply vessels and/or to the vapor deposition chamber.

Referring now to the drawings, FIG. 4 is a schematic representation of a vapor deposition system 100 in one embodiment thereof.

In this illustrative system, a pre-reaction-combating agent is contained in a supply vessel 110. The pre-reaction-combating agent can comprise a pre-reaction suppressant, a free radical inhibitor, a deuterium source, or a combination of two or more of such agents and/or types of such agents.

The pre-reaction-combating agent supply vessel is joined by respective flow lines 112, 114 and 116, to germanium, antimony and tellurium reagent supply vessels, labeled “G,” “S” and “T,” respectively. The germanium precursor in vessel “G” may be a tetraalkyl or tetraamido germanium compound, such as tetramethyl germanium, tetraethyl germanium, tetraallyl germanium, tetrakis(dimethylamino)germane or other organo germanium compounds. Furthermore, precursor “G” may be a germylene compound wherein the lone pair on Ge(II) can react in the gas-phase with chalcogen precursors in the absence of a pre-reaction suppresant. The antimony precursor in vessel “S” can be a trialkyl or triamido antimony compound, such as tributyl antimony, triisopropyl antimony, tris(dimethylamino)antimony or other organo antimony compound. The tellurium precursor in vessel “T” can be a dialkyl or diamido tellurium compound, such as diisopropyl tellurium, dibutyl tellurium, bis[bis(trimethylsilyl)amino]tellurium or other organo tellurium compound.

The pre-reaction-combating agent therefore can be added to any of the germanium, antimony and/or tellurium precursors in the respective “G,” “S” and “T” vessels, via the corresponding flow line(s), which for such purpose may have flow control valves or other flow-modulating components therein.

In the specific process embodiment shown, the germanium, antimony and tellurium precursors are flowed in liquid form in feed lines 118, 120 and 122, respectively, to the mixing chamber 124, and the resulting precursor mixture then is flowed from the mixing chamber 124 in line 126 to vaporizer 128. In the vaporizer, the liquid precursor mixture and pre-reaction-combating agent are volatilized to form a precursor vapor. The precursor vapor then flows in line 130 to the showerhead disperser 134 in vapor deposition chamber 132, for discharge of precursor mixture onto the wafer substrate 136 mounted on susceptor 138 in the deposition chamber.

The precursor vapor contacting the wafer substrate 136 serves to deposit the germanium, antimony and tellurium metals on the substrate, to form a thin film of germanium-antimony-tellurium (GST) material, e.g., for manufacture of a phase change random access memory device.

The contacted precursor vapor, depleted in metals content, is discharged from the vapor deposition chamber 132 in line 140, and flows to the effluent abatement unit 142. In the effluent abatement unit 142, the discharged effluent vapor is treated, e.g., by scrubbing, catalytic oxidation, electrochemical treatment, or in other manner, to yield a final effluent that is discharged from the abatement unit in line 146.

It will be appreciated that these schematic representation of the vapor deposition system shown in FIG. 4 is of an illustrative character, and that numerous other arrangements could be utilized for deployment and use of the pre-reaction-combating agent, including those previously illustratively discussed herein. For example, the pre-reaction-combating agent could be introduced directly to the mixing chamber 124, for blending therein with the respective GST precursors. Alternatively, the pre-reaction-combating agent could be introduced into manifold 118, or other mixing chamber, blender, etc., for combination with the precursor that is being transported to the deposition locus.

The system shown in FIG. 4 employs liquid delivery of the respective precursors. It will be recognized that if solid-phased precursors are employed, then solid delivery techniques may be employed, in which solid precursor is volatilized, e.g., by sublimation of the solid starting material.

In lieu of using a deuterating agent as the pre-reaction-combating agent in the FIG. 4 system, one or more of the germanium, antimony and tellurium precursors could be supplied in the first instance as a deuterated analog of an organo germanium, antimony or tellurium precursor, in which hydrogen substituents of the organo moiety have been replaced with deuterium.

The pre-reaction-combating reagents may be employed in the broad practice of the present invention to produce improved films for the manufacture of semiconductor products. In general, the pre-reaction-combating reagents described herein may be utilized in various combinations in specific applications, to suppress or eliminate pre-reaction of the precursor and provide superior nucleation and final film properties.

### VII. Material Storage

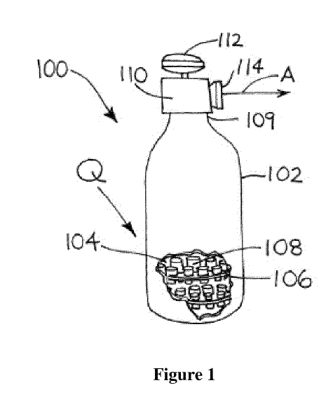

The precursors can be stored in any suitable storage vessel used with any suitable dispensing package. FIG. 1 is a schematic representation of a representative material storage and dispensing package 100 containing an organometallic precursor as described herein.

The material storage and dispensing package 100 includes a vessel 102 that may for example be of generally cylindrical shape as illustrated, defining an interior volume 104 therein. In this specific embodiment, the precursor is a solid at ambient temperature conditions, and such precursor may be supported on surfaces of the trays 106 disposed in the interior volume 104 of the vessel, with the trays having flow passage conduits 108 associated therewith, for flow of vapor upwardly in the vessel to the valve head assembly for dispensing, in use of the vessel.

The solid precursor can be coated on interior surfaces in the interior volume of the vessel, e.g., on the surfaces of the trays 106 and conduits 108. Such coating may be effected by introduction of the precursor into the vessel in a vapor form from which the solid precursor is condensed in a film on the surfaces in the vessel. Alternatively, the precursor solid may be dissolved or suspended in a solvent medium and deposited on surfaces in the interior volume of the vessel by solvent evaporation. In yet another method the precursor may be melted and poured onto the surfaces in the interior volume of the vessel. For such purpose, the vessel may contain substrate articles or elements that provide additional surface area in the vessel for support of the precursor film thereon.

As a still further alternative, the solid precursor may be provided in granular or finely divided form, which is poured into the vessel to be retained on the top supporting surfaces of the respective trays 106 therein. As a further alternative, a metal foam body may be provided in the interior volume of the vessel, which contains porosity of a specific character adapted for retaining the solid particulate precursor for highly efficient vaporization thereof.

The vessel 102 has a neck portion 109 to which is joined the valve head assembly 110. The valve head assembly is equipped with a hand wheel 112 in the embodiment shown. In lieu of a hand wheel, the valve head assembly may in turn be coupled or operatively linked to a controller for automated operation. The valve head assembly 110 includes a dispensing port 114, which may be configured for coupling to a fitting or connection element to join flow circuitry to the vessel. Such flow circuitry is schematically represented by arrow A in FIG. 1, and the flow circuitry may be coupled to a downstream ALD or chemical vapor deposition chamber (not shown in FIG. 1).

In use, the vessel 102 can be heated with a suitable heater, such as a heating jacket, resistance heating elements affixed to the exterior wall surface of the vessel, etc., so that solid precursor in the vessel is at least partially volatilized to provide precursor vapor. The input of heat is schematically shown in FIG. 1 by the reference arrow Q. The precursor vapor is discharged from the vessel through the valve passages in the valve head assembly 110 when the hand wheel 112 or alternative valve actuator or controller is translated so that the valve is in an open position, whereupon vapor deriving from the precursor is dispensed into the flow circuitry schematically indicated by arrow A.

In lieu of solid delivery of the precursor, the precursor may be provided in a solvent medium, forming a solution or suspension. Such precursor-containing solvent composition then may be delivered by liquid delivery and flash vaporized to produce a precursor vapor. The precursor vapor is contacted with a substrate under deposition conditions, to deposit the metal on the substrate as a film thereon.

In one embodiment, the precursor is dissolved in an ionic liquid medium, from which precursor vapor is withdrawn from the ionic liquid solution under dispensing conditions.

As a still further alternative, the precursor may be stored in an adsorbed state on a suitable solid-phase physical adsorbent storage medium in the interior volume of the vessel. In use, the precursor vapor is dispensed from the vessel under dispensing conditions involving desorption of the adsorbed precursor from the solid-phase physical adsorbent storage medium.

Supply vessels for precursor delivery may be of widely varying type, and may employ vessels such as those commercially available from ATMI, Inc. (Danbury, Conn.) under the trademarks SDS, SAGE, VAC, VACSorb, and ProE-Vap, as may be appropriate in a given storage and dispensing application for a particular precursor of the invention.

The precursors of the invention thus may be employed to form precursor vapor for contacting with a substrate to deposit a tellurium-containing thin film thereon.

In a preferred aspect, the invention utilizes the precursors to conduct atomic layer deposition, yielding ALD films of superior conformality that are uniformly coated on the substrate with high step coverage and conformality even on high aspect ratio structures.

Accordingly, the precursors of the present invention enable a wide variety of microelectronic devices, e.g., semiconductor products, flat panel displays, etc., to be fabricated with tellurium-containing films of superior quality.

The present invention will be better understood with reference to the following non-limiting examples.

### Example 1

### Synthesis of Zr(N(Prⁱ)CH₂CH₂CH₂N(Prⁱ))₂

To a 1000 ml flask charged with N1,N3-diisopropylpropane-1,3-diamine (37.98 g, 240 mmol) and 300 ml Et₂O, 400 ml 1.6 M n-butlylithium (0.16 mol) was added slowly at 0° C. The mixture turned turbid gradually with formation of a white precipitate. The mixture was slowly warmed to room temperature over the period of 4 hrs. zirconium(IV) chloride (27.96 g, 120 mmol) was added to the above in-situ made N1,N3-diisopropylpropane-1,3-diamide lithium at 0° C. and the mixture turned yellow gradually with a lots of precipitation. The mixture was warmed to room temperature and refluxed at 55° C. (heated oil bath, 0° C. condenser) overnight. The solvent was removed in vacuo and the residue was dissolved in pentane (450 mL) then filtered to remove LiCl. Pentane was then removed in vacuo and the crude was distilled subsequently at 180° C. (oil bath) and under 150 mtorr vacuum to afford a yellow sticky liquid (33 g, 82 mmol, 68.1% yield).

### Example 2

### Synthesis of Ti(N(Et)CH₂CH₂CH₂N(Et))₂

39.5 ml 1.6 M n-butyllithium (63.2 mmol) was added slowly at 0° C. to a solution of H(N(Et)(CH₂CH₂CH₂N(Et))₂ The mixture turned turbid gradually with formation of a white precipitate. The mixture was warmed to room temperature over the period of 4 hrs. Titanium(IV) chloride (3.64 g, 19.20 mmol) in pentane (50 mL) was added to the above in-situ made N1,N3-diisopropylpropane-1,3-diamide lithium at 0° C. and the mixture turned brown gradually with a lot of precipitation and white smoke observed. The mixture was warmed to room temperature and stirred overnight then filtered to remove LiCl. Pentane was then removed in vacuo to afford the product as a dark brown oil.

While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

What is claimed is:

1. An organometallic precursor of the formula: 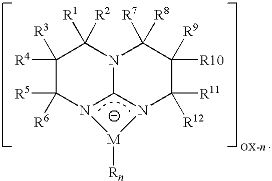
M is a metal, such as Ta, V, Ti, Nb, Pb, Ni, W, Ca, Ba, In, Y, Lanthanides, Zr, Hf,
Ir, Ru, Pt, Cr, Mo, Ge, Al, Si, Ga, Sc, V, Cr, Fe, Sb, Mn, Co, Zn, Cd, Te, Hg, Au,
Ag, Sr, Bi, and the like; but not Cu,
OX is the oxidation state of the metal,
n is integers from 0 to OX integers and
R₁₋₁₂ are, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl and acetylalkyl, and
R is, independently, selected from H, C₁-C₆ alkyl, C₁-C₆ alkoxy, C₃-C₈ cycloalkyl, C₆-C₁₀ aryl, silyl, substituted silyl, aminoalkyl, alkoxyalkyl, aryloxyalkyl, imidoalkyl, amidinates, guanidinates, isourates, β-diketonates, ketoiminates, ketiminates and acetylalkyl.

2. A composition comprising an organometallic precursor of claim 1, and a solvent medium in which said compound is dissolved.

3. The composition of claim 2, wherein the solvent medium comprises a hydrocarbon solvent.

4. The composition of claim 3, wherein the hydrocarbon solvent comprises one or more of alkanes, aromatics and amines.

5. A precursor vapor comprising vapor of an organometallic precursor of claim 1.

6. The composition of claim 2, further comprising a pre-reaction-combating agent for said precursor, said pre-reaction-combating agent being selected from the group consisting of (i) heteroatom (O, N, S) organo Lewis base compounds, (ii) free radical inhibitors, and (iii) deuterium-containing reagents.

7. A method of depositing a metal-containing film on a substrate, comprising volatilizing an organometallic precursor of claim 1 to form a precursor vapor, and contacting the substrate with the precursor vapor under deposition conditions to form the metal-containing film on the substrate.

8. The method of claim 7, wherein the organometallic precursor comprises one or more metal atoms selected from the group consisting of germanium, tellurium, and antimony atoms.

9. The method of claim 7, wherein the film is part of a PCRAM device.

10. The method of claim 7, wherein the film is a GST (GeₓSb_{y}Te_{z}) film, an amorphous GeₓTe_{y} (e.g. GeTe) film, or an amorphous SbₓTe_{y} (e.g. Sb₂Te₃) film.

11. The method of claim 7, wherein the film is an electrode layer, and the precursor vapor is contacted with the substrate under atomic layer deposition or chemical vapor deposition conditions.

12. The method of claim 7, wherein the film is a BiₓTe_{y} film or an SbₓTe_{y} film for use in thermoelectric devices.

13. The method of claim 7, further comprising contacting said substrate, prior to said contact of the vapor phase precursor therewith, with a pre-reaction-combating agent selected from the group consisting of (i) heteroatom (O, N, S) organo Lewis base compounds, (ii) free radical inhibitors, and (iii) deuterium-containing reagents.

14. The method of claim 7, wherein the precursor of claim 1 is undesirably pre-reactive in the vapor phase, said process further comprising introducing to said film during growth thereof a pre-reaction-combating reagent that is effective to passivate a surface of said film or to slow rate of deposition of said film precursor, and after introducing said pre-reaction-combating reagent, reactivating said film with a different film precursor, wherein the pre-reaction-combating reagent is selected from the group consisting of (i) heteroatom (O, N, S) organo Lewis base compounds, (ii) free radical inhibitors, and (iii) deuterium-containing reagents.

15. The method of claim 14, wherein said introducing and reactivating are carried out alternatingly and repetitively.
